(19) United States
(12) Patent Application Publication
(10) Pub. No.: US 2026/0015222 A1
(43) Pub. Date: Jan. 15, 2026

(54) Two stage plating for reduced Ni and NiO layer formation

(71) Applicant: Menlo Microsystems, Inc., Irvine, CA (US)

(72) Inventors: Joleyn Eileen Brewer, Clifton Park, NY (US); Donald Foust, Glenville, NY (US); Christopher Nassar, Hudson, NY (US)

(21) Appl. No.: 18/772,083

(22) Filed: Jul. 12, 2024

(51) Int. Cl. B81B 3/00; B81C 1/00

(52) U.S. Cl. CPC B81B 3/0021; B81C 1/0015; B81B 2201/014; B81B 2203/0118

(57) ABSTRACT

A beam for a microelectromechanical system (MEMS) switch may include a first layer including a nickel alloy and a second layer on at least a portion of the first layer.

### BACKGROUND

Plated metal alloys containing nickel (Ni) are used for several applications including the formation of microelectromechanical system (MEMS) device structures. In particular, nickel containing alloys can be used to form cantilevers and other freestanding or released structures. One such application for gold-nickel alloy cantilever “beams” is as an ohmic switching element within a MEMS architecture. Such beams can be actuated in several ways including mechanically, electrothermally, piezoelectrically, or electrostatically. In all cases, because the structures are freestanding, they are very sensitive to stress and/or a coefficient of thermal expansion (CTE) mismatch in the films that would cause bow when taken through a thermal cycle. In the specific case of electrostatically actuated beams, the force required to pull in the beam (close the beam) can be approximated as the force generated by a parallel plate capacitor. The displacement of the beam is dependent on this force, the beam length, and the mechanical properties of the beam material. Therefore, any bow or deflection in the beam caused by stress or CTE mismatch will have a significant effect on the force required to actuate the beam. In the case of an electrostatic system, this translates to a change in pull-in voltage.

During high temperature processes (for example, when the beam is in an environment with an average temperature of about 200 degrees Celsius to about 450 degrees Celsius), nickel within a nickel alloy can diffuse to the surface of the beam. If this high temperature process is performed in the presence of O₂, this surface nickel can oxidize, forming a high stress NiO layer on the beam surface. As the nickel is oxidized, and the free nickel is consumed, more nickel continues to diffuse to the surface to replace it.

### SUMMARY

A beam for a MEMS switch may include a first layer comprising a nickel alloy; and a second layer on at least a portion of the first layer. The MEMS switch may be deployed within a hermetically sealed device chamber. The second layer may provide a barrier between the first layer and oxygen within the device chamber. This barrier may prevent nickel at the surface of the first layer from oxidizing at elevated temperature processing steps (e.g., the thermocompression-bonding processing step that forms the hermetically sealed device chamber). Even after fabrication processes are completed, intended residual oxygen in the device chamber is available to cause oxidation of nickel to form the NiO layer.

In various example embodiments, the second layer comprises at least one of gold, platinum, or palladium.

In various example embodiments, the first layer comprises a first modulus of elasticity and the second layer comprises a second modulus of elasticity, the second modulus of elasticity being smaller than the first modulus of elasticity.

In various example embodiments, the first layer comprises a first coefficient of thermal expansion and the second layer comprises a second coefficient of thermal expansion, the first coefficient of thermal expansion being substantially similar to the second coefficient of thermal expansion.

In various example embodiments, the second layer is nanocrystalline.

In various example embodiments, the second layer is between 0.05 microns thick and 1.0 microns thick.

In various example embodiments, the first layer is at least 6 microns thick.

In various example embodiments, the second layer is deposited by electroplating.

In various example embodiments, the second layer is deposited by electroless deposition.

In various example embodiments, the nickel alloy comprises a nickel-gold alloy.

In various example embodiments, the first layer comprises 1-8 percent atomic nickel content.

In various example embodiments, the second layer comprises less than 1 percent atomic nickel content.

A method of forming a beam for a MEMS switch may include depositing a first layer on a seed layer, the first layer comprising a nickel alloy; and depositing a second layer on at least a portion of the first layer.

In various example embodiments, the second layer comprises at least one of gold, platinum, or palladium.

The method may further include depositing the second layer by electroplating.

The method may further include depositing the second layer by electroless deposition.

In various example embodiments, the first layer comprises a first modulus of elasticity and the second layer comprises a second modulus of elasticity, the second modulus of elasticity being smaller than the first modulus of elasticity.

In various example embodiments, the first layer comprises a first coefficient of thermal expansion and the second layer comprises a second coefficient of thermal expansion, the first coefficient of thermal expansion being substantially similar to the second coefficient of thermal expansion.

In various example embodiments, the second layer is nanocrystalline.

In various example embodiments, the second layer comprises less than 1 percent atomic nickel content.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a side schematic view of an example embodiment of a MEMS switch that includes a beam comprising a first layer and a second layer.

FIG. 2 is a perspective schematic view of an example embodiment of a beam comprising a first layer and a second layer.

FIG. 3 shows an example method for fabricating a beam of a MEMS system.

FIG. 4 shows a side schematic view of an example embodiment of a MEMS switch in a sealed cavity.

### DETAILED DESCRIPTION

A description of example embodiments follows.

The term “about” as used herein, refers to a value within +/−10% of the value that is associated with the usage of the term, inclusive of the range limits. All ranges included herein are inclusive of range limits.

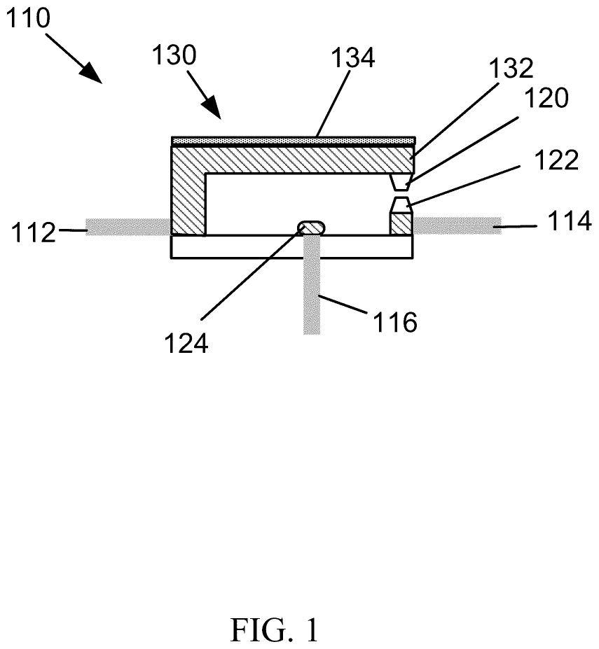

FIG. 1 is a side schematic view of an example embodiment of a MEMS switch 110 that includes a beam 130 comprising a first layer 132 and a second layer 134. A MEMS switch 110 may have an input port 112, an output port 114, and a control port 116, as shown in FIG. 1. The MEMS switch 110 may comprise a beam 130 electrically connected to the input port 112. A first contact 120 may be mechanically and electrically connected to the beam 130, so that the input port 112 is electrically connected to the first contact 120 through the beam 130. A second contact 122 may be disposed near the first contact 120, but not in electrical contact with the first contact 120 when an actuating voltage is not applied to the control port 116. The control port 116 may be electrically coupled to an actuation gate 124 of the MEMS switch 110. When a control signal (for example, voltage) is applied to the control port 116, the actuation gate 124 exerts a force on the beam 130, which causes the beam 130 to deflect such that the first contact 120 touches and electrically couples to the second contact 122, thereby creating a low-impedance electrical path from the input port 112 to the output port 114. In alternative embodiments, the control signal may be applied directly to the actuation gate 124, rather than applied to the control port 116.

A beam 130 for a MEMS switch 110 may comprise a first layer 132 comprising a nickel alloy and a second layer 134 disposed on at least a portion of the first layer 132 or disposed on at least a portion of an outer surface of the first layer 132. In various example embodiments, such as the embodiment shown in FIG. 1, the second layer 134 is disposed on the top surface of the first layer 132. Additionally, or alternatively, the second layer may be disposed on at least one side of the first layer. In alternative embodiments, the second layer may be disposed on a portion of the outer surface of the top and/or side of the first layer.

The second layer 134 may act as a barrier to prevent the oxidation of nickel at the surface of the first layer 132. In various example embodiments, the second layer 134 is thick enough that nickel is not able to diffuse to the surface within the timeframe that the device may be at elevated temperature. For example, in some example embodiments, the second layer 134 is thick enough to prevent nickel from diffusing to the surface during a thermocompression bond process which takes place in an environment that has an average temperature of about 350 degrees Celsius for 1 hour.

The second layer 134 may comprise a material that does not form an oxide in air. In some example embodiments, the second layer 134 may be a pure metal or almost a pure metal. In various example embodiments, the second layer may comprise gold (Au). In various example embodiments, the second layer may comprise platinum (Pt). In various example embodiments, the second layer may comprise palladium (Pd).

The second layer 134 may have a smaller modulus of elasticity than the first layer 132 so that the second layer 134 will not have significant effect on the stiffness of the beam.

The second layer 134 may have a coefficient of thermal expansion that is about the same as the coefficient of thermal expansion of the first layer 132.

The second layer 134 may have a nanocrystalline structure. The nanocrystalline grain boundaries may create irregular paths to the surface of the second layer 134, thereby reducing the likelihood of Ni atoms migrating from the first layer 132 through the second layer 134 to the oxygen-facing surface.

In some example embodiments, the first layer 132 has a thickness of about 6 micrometers. In some example embodiments, the first layer 132 has a thickness of less than about 6 micrometers. In some example embodiments, the first layer 132 has a thickness of greater than about 6 micrometers.

In some example embodiments, the second layer 134 has a thickness of 0.05 microns. In some example embodiments, the second layer 134 has a thickness of less than 0.05 microns. In some example embodiments, the second layer 134 has a thickness of 0.4 microns. In some example embodiments, the second layer 134 has a thickness of less than 0.4 microns. In some example embodiments, the second layer 134 has a thickness of 0.6 microns. In some example embodiments, the second layer 134 has a thickness of less than 0.6 microns. In some example embodiments, the second layer 134 has a thickness of 0.8 microns. In some example embodiments, the second layer 134 has a thickness of less than 0.8 microns. In some example embodiments, the second layer 134 has a thickness of 1.0 micron. In some example embodiments, the second layer 134 has a thickness of less than 1.0 micron. In some example embodiments, the second layer 134 has a thickness greater than 1.0 micron. In some example embodiments, the second layer 134 has a thickness of about 0.2 microns.

In some example embodiments, the first layer 132 comprises about 1-8 percent atomic nickel content. In some example embodiments, the second layer 134 comprises less than 1 percent atomic nickel content.

In some example embodiments, a beam for a MEMS switch may include at least one layer between the first layer and the second layer. In some example embodiments, at least one of the at least one layer between the first layer and the second layer comprises palladium. In some example embodiments, at least one of the at least one layer between the first layer and the second layer comprises platinum. In some example embodiments, at least one of the at least one layer between the first layer and the second layer comprises a material that prevents the migration of nickel from the first layer to the second layer. In some example embodiments, at least one of the at least one layer between the first layer and the second layer comprises a material that reduces the migration of nickel from the first layer to the second layer.

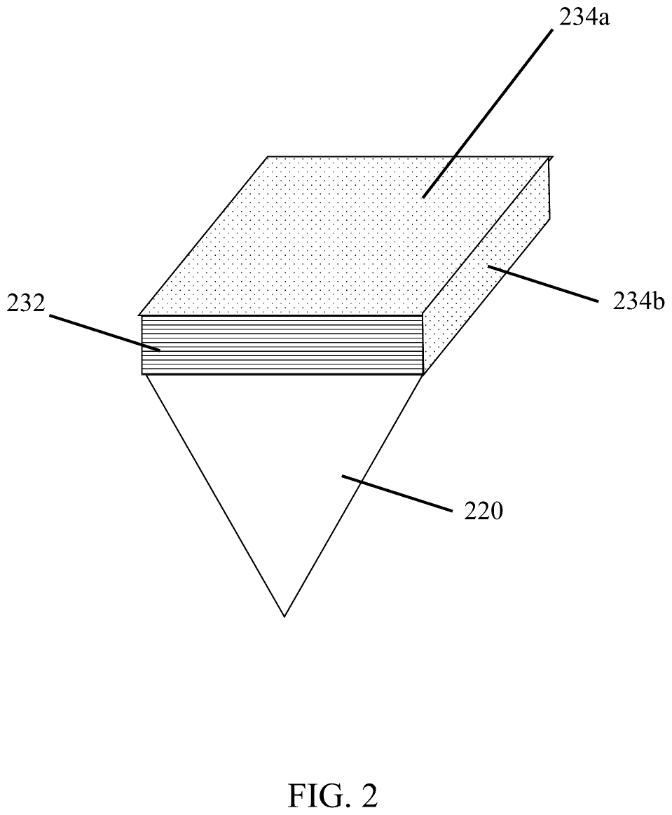

FIG. 2 is a perspective schematic view of an example embodiment of a beam 230 comprising a first layer 232, a second layer 234, and a contact 220. In various example embodiments, such as the embodiment shown in FIG. 2, a portion of the second layer 234a covers a surface at the top of a beam 230. In some example embodiments, a portion of the second layer 234b covers at least one side of the beam 230. In some example embodiments, the second layer covers a top surface and one or more sides of the beam. In some example embodiments, one or more of the characteristics described in connection with any figure herein may apply to the example embodiment shown in FIG. 2.

The second layer may be deposited by electroplating. The second layer may be deposited by electroless deposition. The second layer may be deposited by chemical vapor deposition (CVD). The second layer may be deposited by physical vapor deposition (PVD).

In some example embodiments, a NiAu alloy is deposited using a pulsed plating program with a duty cycle of less than 100%. Then the duty cycle goes to 100% (without pulse plating) the Ni content in the plated film is nearly 0, allowing for plating a nearly pure Au layer on the NiAu beam surface.

In some example embodiments, the first and second layer are formed with a method, comprising:
(1) Electroplating beam material (e.g., NiAu) within a photoresist defined pattern. For example, pulse plating of NiAu chemistry, may be used to achieve about 1-8% Ni content in NiAu alloy beam.
(2) Changing plating conditions or chemistry to plate a low modulus, oxide resistant material on the top surface (e.g., Au). For example, direct current plating of Au (<1% Ni) within the same NiAu plating chemistry on the top surface of the beam.

In some example embodiments, the second layer is plated to the first layer. In some example embodiments, a second layer of pure gold is plated to the first layer.

In some example embodiments, the second layer is sputtered on the first layer. In some example embodiments, the second layer includes sputtered gold.

In some example embodiments, there is a layer between the first layer and the second layer. In some example embodiments, a layer of palladium is between the first layer and the second layer. In some example embodiments, a layer of platinum is between the first layer and the second layer.

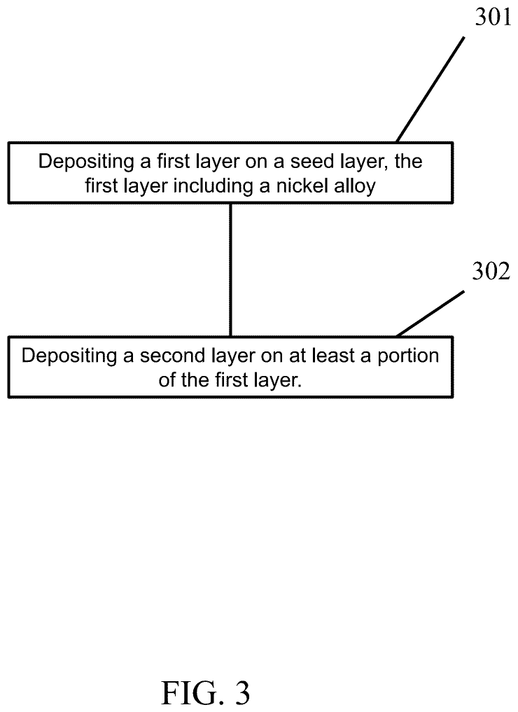

FIG. 3 shows a method of forming a beam for a MEMS switch, comprising: depositing a first layer on a seed layer, the first layer comprising a nickel alloy 301; and depositing a second layer on at least a portion of the first layer 302.

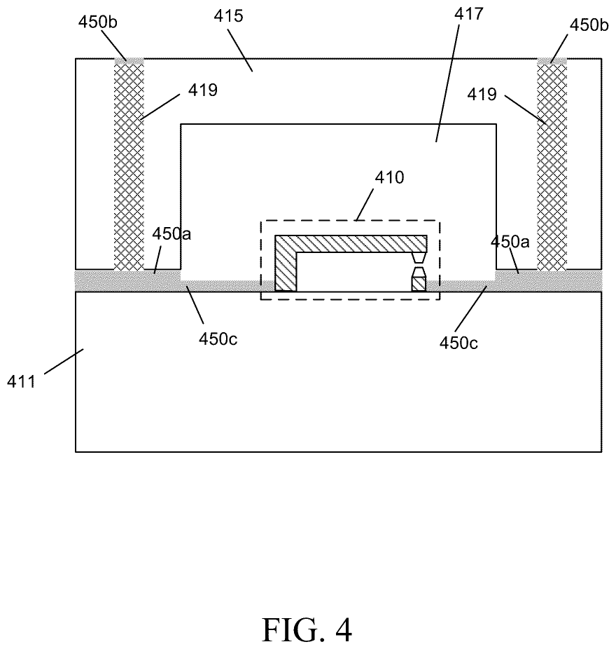

In some example embodiments, a MEMS component may consist of a two-part structure. The first part comprises a MEMS device structure 410 constructed on a glass substrate 411, and the second part comprises a glass lid or cap 415 that surrounds and covers the MEMS device structure 410, as shown in FIG. 4, to form a hermetically sealed cavity 417 in which the MEMS device structure 410 resides. One or more electrical conductors may pass through the glass lid 415 to the MEMS device structure 410, to provide electrical access to the MEMS device structure 410 from outside the sealed cavity 417. These electrical conductors may be in the form of through-glass vias (TGVs) 419 that facilitate the transmission of electrical signals through the glass lid 415 while maintaining the hermeticity of the sealed cavity 417.

The electrically conductive material within the TGV 419 may be copper, with a gold layer 450a coupled to the bottom (i.e., substrate-facing) end of the TGV 419, and a gold layer 450b (external bonding pad) coupled to the top end of the TGV 419. Gold layers 450c are disposed on the substrate 411 and electrically coupled to the MEMS device structure 410. The gold layer 450a at the bottom of the TGV 419 may couple to the gold layer 450c on the substrate 411 by thermal-compression bonding, thereby forming the hermetically sealed cavity 417, as shown in FIG. 4. In some example embodiments, one or more of the characteristics described in connection with any figure herein may apply to the example embodiment shown in FIG. 4.

While example embodiments have been particularly shown and described, it will be understood by those skilled in the art that various changes in form and details may be made therein without departing from the scope of the embodiments encompassed by the appended claims.

1. A beam for a microelectromechanical system (MEMS) switch, comprising:
a first layer comprising a nickel alloy; and
a second layer on at least a portion of the first layer,
wherein the first layer comprises 1-8 percent atomic nickel content.

2. The beam of claim 1, wherein the second layer comprises at least one of gold, platinum, or palladium.

3. The beam of claim 1, wherein the first layer comprises a first modulus of elasticity and the second layer comprises a second modulus of elasticity, the second modulus of elasticity being smaller than the first modulus of elasticity.

4. The beam of claim 1, wherein the first layer comprises a first coefficient of thermal expansion and the second layer comprises a second coefficient of thermal expansion, the first coefficient of thermal expansion being about the same as the second coefficient of thermal expansion.

5. The beam of claim 1, wherein the second layer is nanocrystalline.

6. The beam of claim 1, wherein the second layer is between 0.05 microns thick and 1.0 micron thick.

7. The beam of claim 1, wherein the first layer is at least 6 microns thick.

8. The beam of claim 1, the second layer being deposited by electroplating.

9. The beam of claim 1, the second layer being deposited by electroless deposition.

10. The beam of claim 1, wherein the nickel alloy comprises a nickel-gold alloy.

11. (canceled)

12. The beam of claim 1, wherein the second layer comprises less than 1 percent atomic nickel content.

13. A method of forming a beam for a MEMS switch, comprising:
depositing a first layer on a seed layer, the first layer comprising a nickel alloy; and
depositing a second layer on at least a portion of the first layer,
wherein the first layer comprises 1-8 percent atomic nickel content.

14. The method of claim 13, wherein the second layer comprises at least one of gold, platinum, or palladium.

15. The method of claim 13, further comprising depositing the second layer by electroplating.

16. The method of claim 13, further comprising depositing the second layer by electroless deposition.

17. The method of claim 13, wherein the first layer comprises a first modulus of elasticity and the second layer comprises a second modulus of elasticity, the second modulus of elasticity being smaller than the first modulus of elasticity.

18. The method of claim 13, wherein the first layer comprises a first coefficient of thermal expansion and the second layer comprises a second coefficient of thermal expansion, the first coefficient of thermal expansion being about the same as the second coefficient of thermal expansion.

19. The method of claim 13, wherein the second layer is nanocrystalline.

20. The method of claim 13, wherein the nickel alloy comprises a nickel-gold alloy.

21. (canceled)

22. The method of claim 13, wherein the second layer comprises less than 1 percent atomic nickel content.
